(19) United States
(12) Patent Application Publication
(10) Pub. No.: US 2010/0270554 A1
(43) Pub. Date: Oct. 28, 2010

(54) METHOD OF REFORMING A METAL PATTERN, ARRAY SUBSTRATE, AND METHOD OF MANUFACTURING THE ARRAY SUBSTRATE

(75) Inventors: Sun-Young HONG, Yongin-si (KR); Hong-Sick Park, Suwon-si (KR); Shi-Yul Kim, Yongin-si (KR); Bong-Kyun Kim, Incheon (KR); Young-Joo Choi, Yongin-si (KR); Byeong-Jin Lee, Seoul (KR); Jong-Hyun Choung, Hwaseong-si (KR); Dong-Ju Yang, Seoul (KR); Hyun-Young Jung, Daegu (KR)

Correspondence Address: H.C. PARK & ASSOCIATES, PLC, 8500 LEESBURG PIKE, SUITE 7500, VIENNA, VA, 22182, US

(73) Assignee: SAMSUNG ELECTRONICS CO., LTD., Suwon-si (KR)

(21) Appl. No.: 12/625,096

(22) Filed: Nov. 24, 2009

(30) Foreign Application Priority Data
Apr. 28, 2009 (KR) 2009-36972

(51) Int. Cl. H01L 29/10; B44C 1/22; H01L 21/4763

(52) U.S. Cl. 257/59; 216/23; 438/587; 257/E29.043; 257/E21.495

(57) ABSTRACT

A method of reforming a metal pattern for improving the productivity and reliability of a manufacturing process, an array substrate and a method of manufacturing the array substrate are disclosed. In the method, a first wiring pattern is formed on an insulation substrate. The first wiring pattern is removed. A second wiring pattern is formed on an embossed pattern by using the embossed pattern as an alignment mask. The embossed pattern is defined by a recess formed on a surface of the insulation substrate. Accordingly, the insulation substrate having the recess formed thereon may not be discarded, and may be reused in forming the first wiring pattern. In addition, the embossed pattern defined by the recess is used as an alignment mask, so that the alignment reliability of a metal pattern may be improved.

### CROSS REFERENCE TO RELATED APPLICATION

This application claims priority from and the benefit of Korean Patent Application No. 2009-36972, filed on Apr. 28, 2009, which is hereby incorporated by reference for all purposes as if fully set forth herein.

### BACKGROUND OF THE INVENTION

1. Field of the Invention

Exemplary embodiments of the present invention relate to a method of reforming a metal pattern, an array substrate and a method of manufacturing the array substrate. More particularly, exemplary embodiments of the present invention relate to a method of reforming a metal pattern for a display substrate, an array substrate and a method of manufacturing the array substrate.

2. Discussion of the Background

Generally, a liquid crystal display (LCD) panel includes an array substrate having a switching element formed thereon for driving a pixel area, an opposite substrate facing the array substrate, and a liquid crystal layer disposed between the array substrate and the opposite substrate. The LCD panel displays an image by applying a voltage to the liquid crystal layer to control light transmittance.

The array substrate may include a gate pattern, an active pattern, a data pattern and a pixel electrode sequentially formed on an insulation substrate that may be a glass substrate. The gate pattern may include a gate line and a gate electrode connected to the gate line. The data pattern may include a data line crossing the gate line, a source electrode and a drain electrode.

The gate pattern, the data pattern and the pixel electrode are respectively formed by patterning a metal layer in a photolithography process. The gate pattern may be damaged during or after a gate pattern forming process. When the gate pattern is damaged, the array substrate may not be driven normally. Accordingly, the gate pattern may be removed from the insulation substrate, and reformed on the insulation substrate. That is, the insulation substrate is reused.

However, an etchant or etching gas that is capable of etching a gate metal layer may etch the gate insulation layer, as well as a surface of the insulation substrate, by a predetermined thickness in the process of forming the gate pattern. In addition, the same etchant or etching gas may be used in the process of removing the damaged gate pattern from the insulation substrate, such that the surface of the insulation substrate may be further etched. When the gate pattern is reformed on the insulation substrate having an etched surface, a section of the gate pattern may be formed by etching the insulation substrate again, so that spots may be generated. Accordingly, it is disadvantageous that an insulation substrate on which a damaged gate pattern has been removed has to be discarded, and not reused.

### SUMMARY OF THE INVENTION

Exemplary embodiments of the present invention provide a reforming method of a metal pattern improving the productivity and reliability of a manufacturing process.

Exemplary embodiments of the present invention also provide an array substrate having a gate pattern formed by the above-mentioned method.

Exemplary embodiments of the present invention also provide a method of manufacturing the above-mentioned array substrate.

Additional features of the invention will be set forth in the description which follows, and in part will be apparent from the description, or may be learned by practice of the invention.

An exemplary embodiment of the present invention discloses a method of reforming a metal pattern. In the method, a first wiring pattern is formed on an insulation substrate. The first wiring pattern is removed. A second wiring pattern is formed on an embossed pattern by using the embossed pattern as an alignment mask. The embossed pattern is defined by a recess formed on a surface of the insulation substrate.

An exemplary embodiment of the present invention also discloses an array substrate including an insulation substrate, a gate pattern, a data pattern and a pixel electrode. The insulation substrate includes an embossed pattern defined by a recess formed on a surface of the insulation substrate. The gate pattern is formed on the embossed pattern to have a gate line. The data pattern is formed on the insulation substrate having the gate pattern formed thereon. The data pattern includes a data line crossing the gate line. The pixel electrode is formed on the insulation substrate having the data pattern formed thereon.

An exemplary embodiment of the present invention also discloses a method of manufacturing an array substrate. In the method, a gate pattern having a gate line is formed on an embossed pattern by using the embossed pattern as an alignment mask. The embossed pattern is defined by a recess formed on a surface of the insulation substrate. A data pattern having a data line crossing the gate line is formed on the insulation substrate having the gate pattern formed thereon. A pixel electrode is formed on the insulation substrate having the data pattern formed thereon.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the principles of the invention.

FIG. 1 is a plan view illustrating an array substrate according to an exemplary embodiment of the present invention.

FIG. 2 is a cross-sectional view taken along line I-I′ of FIG. 1.

FIG. 3, FIG. 4, FIG. 5, FIG. 6, FIG. 7, FIG. 8 and FIG. 9 are cross-sectional views illustrating an exemplary embodiment of a method of manufacturing the array substrate of FIG. 2.

FIG. 10, FIGS. 11 and 12 are cross-sectional views illustrating another exemplary embodiment of a method of manufacturing the array substrate of FIG. 2.

FIG. 13 and FIG. 14 are cross-sectional views illustrating still another exemplary embodiment of a method of manufacturing the array substrate of FIG. 2.

### DETAILED DESCRIPTION OF THE ILLUSTRATED EMBODIMENTS

The invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough, and will fully convey the scope of the invention to those skilled in the art. In the drawings, the size and relative sizes of layers and regions may be exaggerated for clarity.

It will be understood that when an element or layer is referred to as being “on,” “connected to” or “coupled to” another element or layer, it can be directly on, directly connected to or directly coupled to the other element or layer, or intervening elements or layers may be present. In contrast, when an element or layer is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments of the invention are described herein with reference to cross-sectional illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, the present invention will be described in detail with reference to the accompanying drawings.

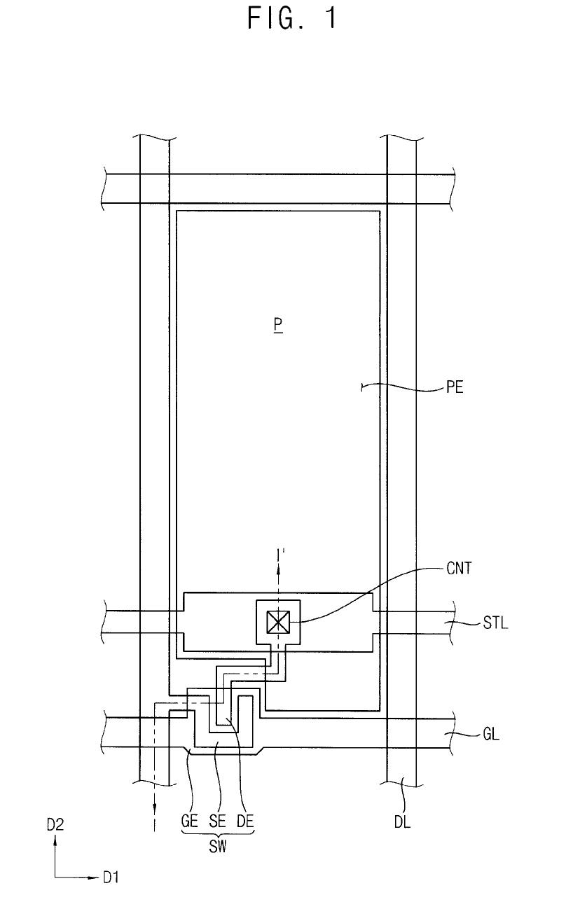

FIG. 1 is a plan view illustrating an array substrate according to an exemplary embodiment of the present invention.

Referring to FIG. 1, the array substrate according to an exemplary embodiment of the present invention includes a gate line GL, a data line DL, a thin-film transistor (TFT) SW that is a switching element, a storage line STL and a pixel electrode PE.

The gate line GL extends in a first direction D1. The gate lines GL are arranged spaced apart in a second direction D2 different from the first direction D1. The first direction D1 may be perpendicular to the second direction D2. The data line DL extends in the second direction D2. The data lines DL are arranged spaced apart in the first direction D1. The data line DL crosses the gate line GL to define a pixel part P of the array substrate. The TFT SW and the pixel electrode PE are formed on the pixel part P. The storage line STL may be formed in parallel with the gate line GL to cross the pixel part P.

The TFT SW includes a gate electrode GE, a source electrode SE and a drain electrode DE. The gate electrode GE is connected to the gate line GL. The source electrode SE is connected to the data line DL. The drain electrode DE is spaced apart from the source electrode SE. A portion of the drain electrode DE overlaps with the storage line STL. A terminal portion of the drain electrode DE overlaps with the storage line STL, and a terminal portion of the drain electrode DE contacts the pixel electrode PE, so that a storage capacitor Cst of the pixel part P may be formed.

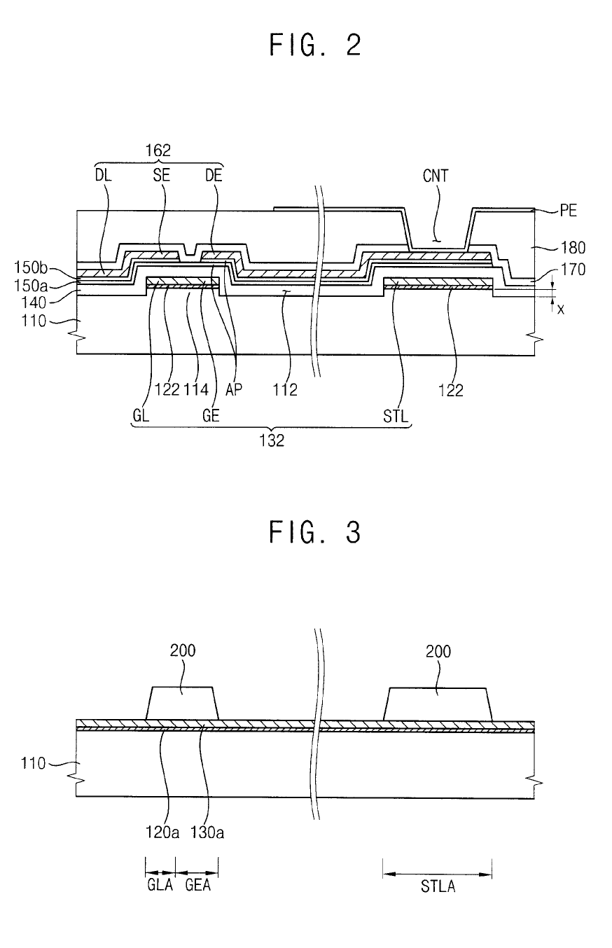

FIG. 2 is a cross-sectional view taken along line I-I′ of FIG. 1.

Referring to FIG. 1 and FIG. 2, the array substrate includes a gate pattern 132, a gate insulation layer 140, a semiconductor layer 150a, an ohmic contact layer 150b, a data pattern 162, a passivation layer 170, a planarization layer 180 and a pixel electrode PE that are sequentially formed on an insulation substrate 110.

The insulation substrate 110 may be a transparent substrate. For example, the insulation substrate 110 may include glass. The insulation substrate 110 includes an embossed pattern 114 defined by a recess 112 formed on a surface of the insulation substrate 110. The recess 112 is formed by being depressed from an initial surface of the insulation substrate 110. Accordingly, the embossed pattern 114 is defined as a relatively embossed pattern by the recess 112. A first height ‘x’ of the embossed pattern 114 may be defined as a distance between a lower surface and a higher surface of the insulation substrate 110. That is, the first height ‘x’ of the embossed pattern 114 may be substantially equal to the depth of the recess 112.

The gate pattern 132 is formed on the embossed pattern 114 along the embossed pattern 114. The shape of the gate pattern 132 may be identical to the shape of the embossed pattern 114 when viewed in a plan view. The gate pattern 132 includes the gate line GL, the gate electrode GE and the storage line STL. The gate line GL, the gate electrode GE and the storage line STL are a wiring pattern substantially applying a signal. For example, the wiring pattern may include copper (Cu).

The array substrate may further include a buffer pattern 122 formed below the gate pattern 132. The buffer pattern 122 may improve adhesive properties between the wiring pattern and the insulation substrate 110. For example, the buffer pattern 122 may include titanium (Ti). The shape of the buffer pattern 122 may be identical to the shape of the gate pattern 132 when viewed in a plan view.

The gate insulation layer 140 is formed on the insulation substrate 110 having the gate pattern 132 formed thereon. For example, the gate insulation layer 140 may include silicon oxide, silicon nitride, etc.

The semiconductor layer 150a and the ohmic contact layer 150b are formed between the gate insulation layer 140 and the data pattern 162. The semiconductor layer 150a and the ohmic contact layer 150b are disposed between the gate electrode GE and the source electrode SE, and are disposed between the gate electrode GE and the drain electrode DE. The semiconductor layer 150a and the ohmic contact layer 150b may be defined as an active pattern AP of the TFT SW. A portion of semiconductor layer 150a may be exposed where the source electrode SE and the drain electrode DE are spaced apart from each other.

The data pattern 162 contacts the ohmic contact layer 150b. The shape of the data pattern 162 may be identical to that of the semiconductor layer 150a and the ohmic contact layer 150b when viewed in a plan view. The data pattern 162 includes the data line DL, the source electrode SE and the drain electrode DE.

The passivation layer 170 is formed on the insulation substrate 110 having the data pattern 162 formed thereon. The passivation layer 170 may be formed of silicon oxide, silicon nitride, etc. The planarization layer 180 is formed on the passivation layer 170. The planarization layer 180 may include a photoresist material. A contact hole CNT exposing a terminal portion of the drain electrode DE is formed through the passivation layer 170 and the planarization layer 180.

The pixel electrode PE contacts a terminal portion of the drain electrode DE through the contact hole CNT. The pixel electrode PE may be electrically connected to the TFT SW through the contact hole CNT.

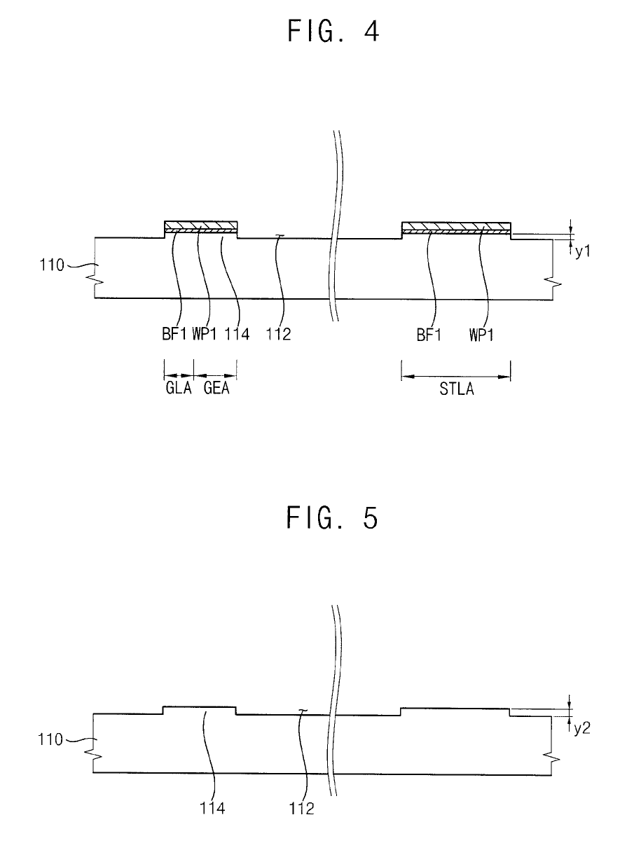

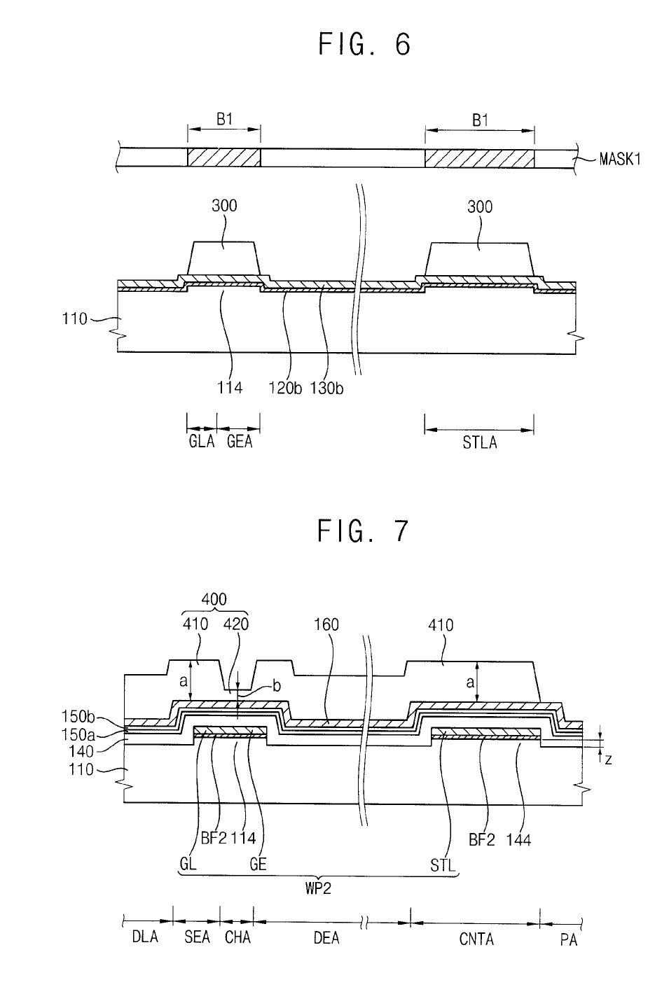

FIG. 3, FIG. 4, FIG. 5, FIG. 6, FIG. 7, FIG. 8, and FIG. 9 are cross-sectional views illustrating an exemplary embodiment of a method of manufacturing the array substrate of FIG. 2.

FIG. 3 and FIG. 4 are cross-sectional views illustrating a process of forming a first buffer pattern and a first wiring pattern. FIG. 5 is a cross-sectional view illustrating a process of removing a first buffer pattern and a first wiring pattern. FIG. 6 is a cross-sectional view illustrating a process of forming a second buffer pattern and a second wiring pattern.

Referring to FIG. 3, a first buffer layer 120a and a first wiring layer 130a are sequentially formed on the insulation substrate 110. For example, the first buffer layer 120a may include titanium (Ti), and the first wiring layer 130a may include copper (Cu).

A first photo pattern 200 is formed on the insulation substrate 110 having the first wiring layer 130a formed thereon. The first photo pattern 200 is respectively formed on a gate line area GLA, a gate electrode area GEA and a storage line area STLA of the insulation substrate 110. The gate line area GLA is an area where the gate line GL is to be formed. The gate electrode area GEA is an area where the gate electrode GE is to be formed. The storage line area STLA is an area where the storage line STL is to be formed.

Referring to FIG. 4, the first wiring layer 130a and the first buffer layer 120a are patterned to form a first wiring pattern WP1 and a first buffer pattern BF1. The first wiring pattern WP1 is a first gate pattern formed on the insulation substrate 110.

For example, the first wiring layer 130a and the first buffer layer 120a may be wet-etched by using an etchant, and the first photo pattern 200 is used as an etch-stop layer. The etchant may simultaneously etch the first line layer 130a and the first buffer layer 120a. The etchant may be etchant including fluorine (F).

The etchant etches the first wiring layer 130a and the first buffer layer 120a, and etches a portion of a surface of the insulation substrate 110 at the same time. Accordingly, the recess 112 is formed on the surface of the insulation substrate 110. The recess 112 may be formed on the entire area of the insulation substrate 110 surface except for the gate line area GLA, the gate electrode area GEA and the storage line area STLA. The embossed pattern 114 defined by the recess 112 is formed on the gate line area GLA, the gate electrode GEA and the storage line area STLA. The embossed pattern 114 has a second height ‘y1’. The second height ‘y1’ may be substantially less than the first height ‘x’.

Then, the first wiring pattern WP1 is inspected for defects. When the first wiring pattern WP1 is damaged by the etchant or other factors, the first wiring pattern WP1 and the first buffer pattern BF1 are removed to reform the first wiring pattern WP1

Referring to FIG. 5, the first wiring pattern WP1 and the first buffer pattern BF1 are removed from the insulation substrate 110. That is, the first gate pattern is removed from the insulation substrate 110. For example, the first wiring pattern WP1 and the first buffer pattern BF1 may be removed by using the etchant including fluorine. The etchant may simultaneously remove the first wiring pattern WP1 and the first buffer pattern BF1. As the first wiring pattern WP1 and the first buffer pattern BF1 are removed, the depth of the recess 112 may become greater, so that a third height ‘y2’ of the embossed pattern 114 may be substantially greater than the second height ‘y1’. The third height ‘y2’ is less than the first height ‘x’.

In another example, the first wiring pattern WP1 may be removed by using an etchant not including fluorine. Then, the first buffer pattern BF1 may be removed by using an etching gas. The etching gas may not include fluorine. Accordingly, in removing the first wiring pattern WP1 and the first buffer pattern BF1, a third height ‘y2’ of the embossed pattern 114 may be the same as the second height ‘y1’ without substantially changing the depth of the recess 112.

Referring to FIG. 6, a second buffer layer 120b and a second wiring layer 130b are formed on the insulation substrate 110 having the embossed pattern 114 formed thereon. A second photo pattern 300 is formed on the second wiring layer 130b. The second photo pattern 300 may be formed by using the embossed pattern 114 as an alignment mask. The second buffer layer 120b is substantially identical to the first buffer layer 120a. The second wiring layer 130b is substantially identical to the first wiring layer 130a.

For example, a photoresist layer is formed on the insulation substrate 110 having the second wiring layer 130b formed thereon, and a first mask MASK1 is disposed on the insulation substrate 110 having the photoresist layer formed thereon. The photoresist layer may be formed of a positive type photoresist composition. Then, the first mask MASK1 includes a first light-blocking member B1. The first light-blocking member B1 may be disposed on the gate line area GLA, the gate electrode area GEA and the storage line area STLA. A remaining area excluding the first light-blocking member B1 of the first mask MASK1 may be a light-transmitting portion. The first mask MASK1 is disposed on the insulation substrate 110 by using the embossed pattern 114 as an alignment mask. That is, the first mask MASK1 may be disposed to correspond the first light-blocking member B1 with the embossed pattern 114. In contrast, when the photoresist layer is formed of a negative type photoresist composition, the first light-blocking member B1 and the light-transmitting portion of the first mask MASK1 may be reversed.

Light is irradiated onto the first mask MASK1 to expose the photoresist layer, and the photoresist layer is developed, so that the second photo pattern 300 is formed. The second wiring layer 130b and the second buffer layer 120b are etched by using the second photo pattern 300 as an etch-stop layer. The second wiring layer 130b and the second buffer layer 120b may be patterned by using an etchant including fluorine.

FIG. 7, FIG. 8 and FIG. 9 are cross-sectional views illustrating a process of forming a data pattern.

Referring to FIG. 7, the second wiring layer 130b and the second buffer layer 120b are patterned to form a second wiring pattern WP2 and a second buffer pattern BF2. The second wiring pattern WP2 includes the gate line GL, the gate electrode GE and the storage line STL. The second wiring pattern WP2 substantially forms the gate pattern 132 shown in FIG. 2. The second buffer pattern BF2 may increase an adhesive strength between the second wiring pattern WP2 and the insulation substrate 110. The second buffer pattern BF2 substantially corresponds to the buffer pattern 122 of FIG. 2.

As the second wiring pattern WP2 and the second buffer pattern BF2 are formed by using the etchant including fluorine, a fourth height ‘z’ of the embossed pattern 114 is formed substantially greater than the third height ‘y2’. The fourth height ‘z’ may be substantially the same as the first height ‘x’.

As described above, in forming the first wiring pattern WP1, the insulation substrate 110 having the recess 112 formed thereon may not be discarded, and may be reused in forming the second wiring pattern WP2. In addition, the embossed pattern 114 defined by the recess 112 is used as an alignment mask in forming the second wiring pattern WP2, so that the alignment reliability of the second wiring pattern WP2 may be improved.

The gate insulation layer 140, the semiconductor layer 150a, the ohmic contact layer 150b and a data metal layer 160 are sequentially formed on the insulation substrate 110 having the second wiring pattern WP2. A third photo pattern 400 is formed on the data metal layer 160. The third photo pattern 400 includes a first thickness portion 410 having a first thickness ‘a’ and a second thickness portion 420 having a second thickness ‘b’. The first thickness ‘a’ is greater than the second thickness ‘b’. The first thickness portion 410 may be formed on a data line area DLA, a source electrode area SEA, a drain electrode area DEA and a contact area CNTA. The second thickness portion 420 may be formed on a channel area CHA between the source electrode area SEA and the drain electrode area DEA. The third photo pattern 400 is not formed on the pixel area PA to expose the data metal layer 160 of the pixel area PA. The data line area DLA is an area where the data line DL is to be formed. The source electrode area SEA is an area where the source electrode SE is to be formed. The drain electrode area DEA and the contact area CNTA are areas where the drain electrode DE is to be formed. The pixel area PA is an area where the pixel electrode PE is to be formed.

The gate insulation layer 140, the semiconductor layer 150a, the ohmic contact layer 150b and the data metal layer 160 may be patterned by using the third photo pattern 400 as an etch-stop layer.

Referring to FIG. 8, the semiconductor layer 150a, the ohmic contact layer 150b and the data metal layer 160 of the pixel area PA are removed to expose the gate insulation layer 140 of the pixel area PA.

Then, an etch-back process of the third photo pattern 400 is performed to form a remaining pattern 430. The third photo pattern 400 is etched to remove the second thickness portion 420 and a portion of the first thickness portion 410. A remainder of the first thickness portion 410 may be defined as the remaining pattern 430. A thickness ‘c’ of the remaining pattern 430 may be substantially the same as a difference between the first thickness ‘a’ and the second thickness ‘b’. Accordingly, the remaining pattern 430 is disposed on the data line area DLA, the source electrode area SEA, the drain electrode area DEA and the contact area CNTA. The remaining pattern 430 exposes the data metal layer 160 of the channel area CHA.

Referring to FIG. 9 and FIG. 2, the data metal layer 160 is patterned by using the remaining pattern 430 as an etch-stop layer. The data metal layer 160 of the channel area CHA is removed to form the source electrode SE and the drain electrode DE. Accordingly, the data pattern 162 may be formed such that it has the data line DL, the source electrode SE and the drain electrode DE.

The ohmic contact layer 150b of the channel area CHA is exposed through the metal layer 160 between the source electrode SE and the drain electrode DE. The exposed ohmic contact layer 150b is removed by using the remaining pattern 430, source electrode SE and the drain electrode DE as an etch-stop layer to form the active pattern AP.

The passivation layer 170 is formed on the insulation substrate 110 having the data pattern 162 formed thereon. The planarization layer 180 is formed on the insulation substrate 110 having the passivation layer 170 formed thereon. The planarization layer 180 is exposed and developed to pattern the planarization layer 180. The passivation layer 170 is patterned by using the patterned planarization layer 180 to form the contact hole CNT exposing a terminal portion of the drain electrode DE.

A transparent electrode layer is formed on the insulation substrate 110 having the contact hole CNT formed thereon through the planarization layer 180 and the passivation layer 170. The transparent electrode layer is patterned to form the pixel electrode PE. Accordingly, the array substrate of FIG. 2 is manufactured.

According to the present exemplary embodiment, the first wiring pattern WP1 determined to be defective is removed by using an etchant including fluorine. Even if the recess 112 is formed on a surface of the insulation substrate 110, the embossed pattern 114 defined by the recess 112 is used as an alignment mask in forming the second wiring pattern WP2, so that the alignment reliability of the second wiring pattern WP2 may be improved. In addition, the insulation substrate 110 may be reused, so that an increase in manufacturing costs of the array substrate may be prevented. Accordingly, the productivity and reliability of an array substrate may be improved.

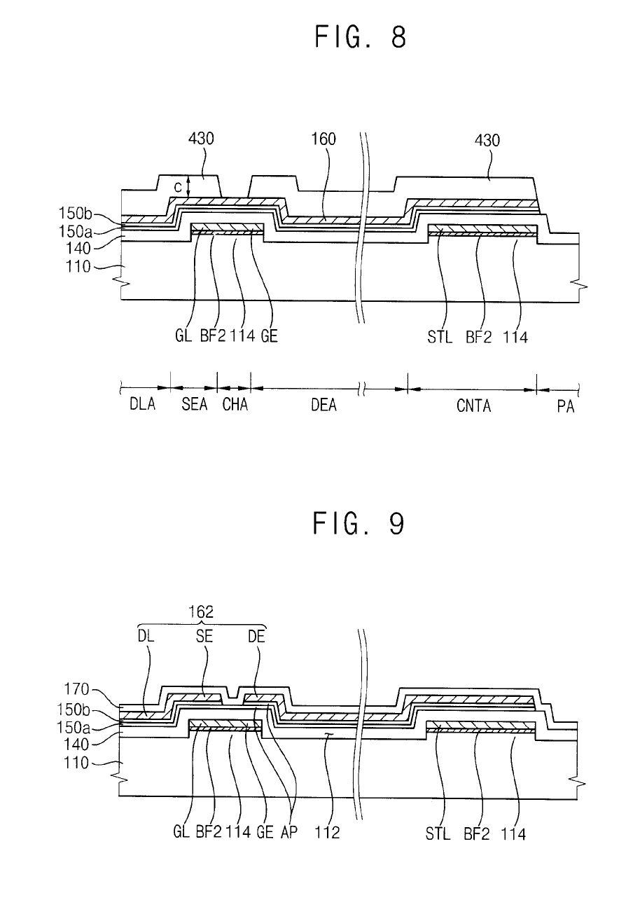

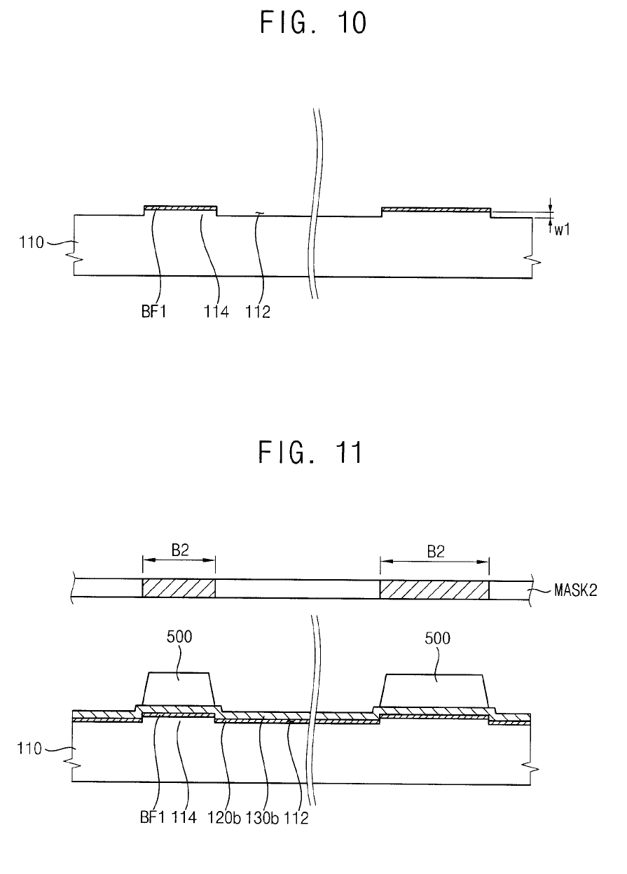

FIG. 10, FIG. 11, and FIG. 12 are cross-sectional views illustrating another exemplary embodiment of a method of manufacturing the array substrate of FIG. 2.

In the present exemplary embodiment, the method of manufacturing the array substrate is substantially identical to the method described with reference to FIG. 3 and FIG. 4 in so far as the first buffer pattern BF1 and the first wiring pattern WP1 are formed on the insulation substrate 110 and the embossed pattern 114 is defined by the recess 112 formed in the process of forming the first buffer pattern BF1 and the first wiring pattern WP1. Accordingly, any further description thereof will be omitted here.

Referring to FIG. 4 and FIG. 10, the first wiring pattern WP1 is inspected for defects. The first wiring pattern WP1 determined to be defective is removed by using an etchant not including fluorine. The etchant not including fluorine does not etch the insulation substrate 110, so that a fifth height ‘w1’ of the embossed pattern 114 may be substantially the same as the second height ‘y1’ of FIG. 4.

Referring to FIG. 11, the second buffer layer 120b and the second wiring layer 130b are sequentially formed on the insulation substrate 110 having the first buffer pattern BF1 disposed on the embossed pattern 114. The thickness of the second buffer layer 120b may be less than the thickness of the first buffer pattern BF1. Accordingly, the second buffer layer 120b may be substantially formed on the entire area of the insulation substrate 110 surface except for an area having the first buffer pattern BF1 formed thereon. That is, the second buffer layer 120b is formed on the insulation substrate 110 surface in the recess 112.

A fourth photo pattern 500 is formed on the insulation substrate 110 having the second wiring layer 130b thereon, as follows. A photoresist layer is formed on the insulation substrate 110 having the second wiring layer 130b thereon. A second mask MASK2 is disposed on the photoresist layer. The photoresist layer is exposed and is developed to form the fourth photo pattern 500. When the second mask MASK2 is disposed on the insulation substrate 110 having the photoresist layer formed thereon, the embossed pattern 114 and the first buffer pattern BF1 are used as an alignment mask. The second mask MASK2 includes a second light-blocking member B2. The second light-blocking member B2 is disposed on the embossed pattern 114.

Referring to FIG. 12, the second wiring layer 130b and the second buffer layer 120b are patterned by using the etchant including fluorine, and the fourth photo pattern 500 is used as an etch-stop layer. The second wiring layer 130b is patterned to form the second wiring pattern WP2. The second wiring pattern WP2 includes the gate electrode GE connected to the gate line GL, and the storage line STL. The second buffer layer 120b is removed by using the etchant including fluorine. A sixth height ‘w2’ of the embossed pattern 114 may be higher than the fifth height ‘w1’ due to etching a portion of the insulation substrate 110 by using the etchant including fluorine.

Accordingly, the buffer pattern BF1 and the second wiring pattern WP2 may be disposed on the embossed pattern 114. The first buffer pattern BF1 corresponds to the buffer pattern 122 of FIG. 2. The second wiring pattern WP2 corresponds to the gate pattern 132 of FIG. 2.

The process for manufacturing the array substrate of FIG. 2 after forming the second wiring pattern WP2 is substantially identical to the process described with reference to FIG. 7, FIG. 8, and FIG. 9. Accordingly, any further description thereof will be omitted here.

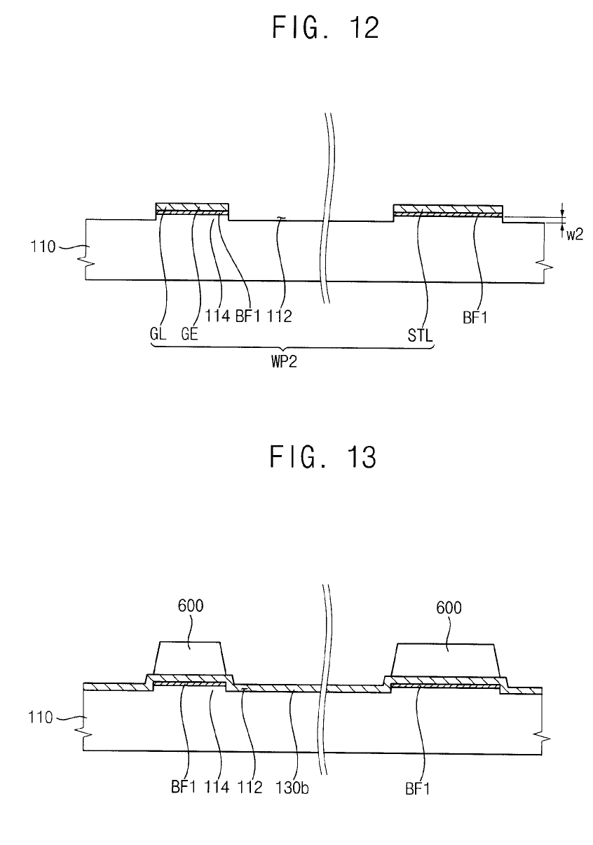

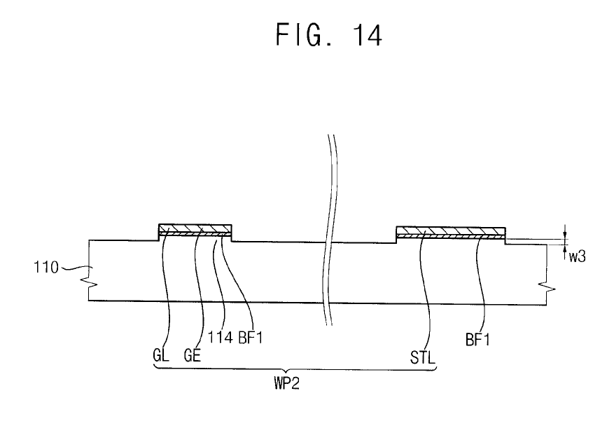

FIG. 13 and FIG. 14 are cross-sectional views illustrating still another exemplary embodiment of a method of manufacturing the array substrate of FIG. 2.

In the present exemplary embodiment, the method of manufacturing the array substrate is substantially identical to the method described with reference to FIG. 3 and FIG. 4 in as far as the first buffer pattern BF1 and the first wiring pattern WP1 are formed on the insulation substrate 110 and the embossed pattern 114 is defined by the recess 112 formed in the process of forming the first buffer pattern BF1 and the first wiring pattern WP1. Accordingly, any further description thereof will be omitted here.

Then, the first wiring pattern WP1 is inspected for defects. The first wiring pattern WP1 having defects is removed. The process of removing the first wiring pattern WP1 is substantially identical to the process described with reference to FIG. 10. Accordingly, any further description thereof will be omitted here.

Referring to FIG. 13, the second wiring layer 130b is formed on the insulation substrate 110 having the first buffer pattern BF1 formed thereon. A fifth photo pattern 600 is formed on the second wiring layer 130b, as follows. A photoresist layer is formed on the insulation substrate having the second wiring layer 130b thereon. A third mask MASK3 (not shown) is disposed on the photoresist layer. The photoresist layer is exposed and is developed to form the fifth photo pattern 600. When the third mask MASK3 is disposed on the insulation substrate 110 having the photoresist layer formed thereon, the embossed pattern 114 and the first buffer pattern BF1 are used as an alignment mask. The third mask MASK3 includes a third light-blocking member. The third light-blocking member is disposed on the embossed pattern 114. A critical dimension (CD) of the third light-blocking member may be larger than a CD of a fourth light-blocking member of a fourth mask (not shown) corresponding to the first photo pattern 200 (shown in FIG. 3) in a process of forming the first wiring pattern WP1.

Referring to FIG. 14, the second wiring layer 130b is patterned by using the etchant not including fluorine, and the fifth photo pattern 600 is used as an etch-stop layer. The second wiring layer 130b is patterned to form the second wiring pattern WP2. The second wiring pattern WP2 includes the gate electrode GE connected to the gate line GL, and the storage line STL. A seventh height ‘w3’ of the embossed pattern 114 may be substantially the same as the fifth height ‘w1’ of FIG. 11 due to not etching a portion of the insulation substrate 110 by using the etchant not including fluorine.

Accordingly, the buffer pattern BF1 and the second wiring pattern WP2 may be disposed on the embossed pattern 114. The first buffer pattern BF1 corresponds to the buffer pattern 122 of FIG. 2. The second wiring pattern WP2 corresponds to the gate pattern 132 of FIG. 2.

The process for manufacturing the array substrate of FIG. 2 after forming the second wiring pattern WP2 is substantially identical to the process described with reference to FIG. 7, FIG. 8, and FIG. 9. Accordingly, any further description thereof will be omitted here.

Referring to FIG. 3 and FIG. 4, another exemplary embodiment of a method of manufacturing the array substrate of FIG. 2 will be described hereinafter.

Referring to FIG. 3, the first buffer layer 120a and the first wiring layer 130a are sequentially formed on the insulation substrate 110. The first photo pattern 200 is formed on the insulation substrate 110 having the first wiring layer 130a formed thereon.

Referring to FIG. 4, the first wiring layer 130a and the first buffer layer 120a are patterned by using the first photo pattern 200 as an etch-stop layer to form the first buffer pattern BF1 and the first wiring pattern WP1. The first wiring layer 130a is wet-etched by using the etchant not including fluorine. Accordingly, the first wiring pattern WP1 is formed on the first buffer layer 120a. Then, the first buffer layer 120a is patterned by using the first photo pattern 200 and the first wiring pattern WP1 as an etch-stop layer. The first buffer layer 120a is wet-etched by using the first etchant including fluorine. The first etchant including fluorine may selectively etch the first buffer layer 120a. The first etchant including fluorine is used in the process described with reference to FIG. 3, FIG. 4, and FIG. 5. An element of the first etchant including fluorine is different from an element of the second etchant including fluorine simultaneously etching the first buffer layer 120a and the first wiring layer 130a. Thus, the first buffer pattern BF1 is formed below the first wiring pattern WP1.

As described above, the process for manufacturing the array substrate of FIG. 2 after forming the first buffer pattern BF1 and the first wiring pattern WP1 is substantially identical to the process described with reference to FIG. 9, FIG. 10, FIG. 11, and FIG. 12. Accordingly, any further description thereof will be omitted here.

Optionally, the process for manufacturing the array substrate of FIG. 2 after forming the first buffer pattern BF1 and the first wiring pattern WP1 is substantially identical to the process described with reference to FIG. 7, FIG. 8, FIG. 9, FIG. 13 and FIG. 14. Accordingly, further description thereof will be omitted here.

In the present invention, an etchant or etching gas capable of damaging an insulation substrate may be used in a photolithography process, and the insulation substrate may be reused to be used in another photolithography process. Accordingly, the productivity and reliability of an array substrate may be improved.

According to the method of reforming a metal pattern, the array substrate and the method of manufacturing the array substrate, an insulation substrate having a recess formed during a process in which a first wiring pattern is formed may not be discarded, and may be reused during the process in which the second wiring pattern is formed. In addition, the embossed pattern defined by the recess is used as an alignment mask when the second wiring pattern is formed, so that the alignment reliability of the second wiring pattern may be improved. Accordingly, the productivity and reliability of an array substrate may be improved.

The foregoing is illustrative of the present invention and is not to be construed as limiting thereof. Although a few exemplary embodiments of the present invention have been described, those skilled in the art will readily appreciate that many modifications are possible in the exemplary embodiments without materially departing from the novel teachings and advantages of the present invention. Accordingly, all such modifications are intended to be included within the scope of the present invention as defined in the appended claims and their equivalents. In the claims, means-plus-function clauses are intended to cover the structures described herein as performing the recited function and not only structural equivalents but also equivalent structures. Therefore, it is to be understood that the foregoing is illustrative of the present invention and is not to be construed as limited to the specific exemplary embodiments disclosed, and that modifications to the disclosed exemplary embodiments, as well as other exemplary embodiments, are intended to be included within the scope of the appended claims and their equivalents. The present invention is defined by the following claims, with equivalents of the claims to be included therein.

What is claimed is:

1. A method of reforming a metal pattern, the method comprising:
forming a first wiring pattern on a substrate;
removing the first wiring pattern; and
forming a second wiring pattern on an embossed pattern by using the embossed pattern as an alignment mask, the embossed pattern being defined by a recess formed on a surface of the substrate.

2. The method of claim 1, further comprising:
forming a buffer pattern, the buffer pattern being disposed between the embossed pattern and the first wiring pattern,
wherein the buffer pattern and the first wiring pattern are removed in removing the first wiring pattern by using an etchant comprising fluorine.

3. The method of claim 1, further comprising:
forming a buffer pattern, the buffer pattern being disposed between the embossed pattern and the first wiring pattern; and
removing the buffer pattern by using an etching gas after removing the first wiring pattern.

4. The method of claim 1, further comprising:
forming a buffer pattern, the buffer pattern being disposed between the embossed pattern and the second wiring pattern.

5. The method of claim 1, further comprising:
forming a first buffer pattern, the buffer pattern being disposed between the substrate and the first wiring pattern and being formed before removing the first wiring pattern.

6. The method of claim 5, wherein the first wiring pattern is formed by patterning a first wiring layer formed on the substrate by using an etchant comprising fluorine, and
wherein the first buffer pattern is formed by patterning a first buffer layer formed below the first wiring layer by using an etchant comprising fluorine.

7. The method of claim 5, wherein forming the second wiring pattern comprises:
forming a second buffer layer on the recess of the substrate having the first buffer pattern disposed on the embossed pattern;
forming a second wiring layer on the first buffer layer and the second buffer layer; and
patterning the second buffer layer and the second wiring layer by using an etchant comprising fluorine.

8. The method of claim 5, wherein forming the second wiring pattern comprises:
forming a second wiring layer on the substrate having the first buffer pattern disposed on the embossed pattern; and
patterning the second wiring layer by using an etchant comprising fluorine.

9. An array substrate, comprising:
a substrate comprising an embossed pattern defined by a recess formed on a surface of the substrate;
a gate pattern disposed on the embossed pattern and comprising a gate line;
a data pattern disposed on the substrate, the data pattern comprising a data line crossing the gate line; and
a pixel electrode disposed on the substrate.

10. The array substrate of claim 9, further comprising:
a buffer pattern disposed between the embossed pattern and the gate pattern.

11. A method of manufacturing an array substrate, the method comprising:
forming a gate pattern comprising a gate line on an embossed pattern by using the embossed pattern as an alignment mask, the embossed pattern being defined by a recess formed on a surface of a substrate;
forming a data pattern comprising a data line crossing the gate line on the substrate; and
forming a pixel electrode on the substrate.

12. The method of claim 11, further comprising:
forming a first buffer layer and a first wiring layer on a planar surface of the substrate before forming the gate pattern;
forming a first buffer pattern and a first wiring pattern by patterning the first buffer layer and the first wiring layer by using an etchant comprising fluorine; and
removing the first buffer pattern and the first wiring pattern.

13. The method of claim 12, wherein the first buffer pattern and the first wiring pattern are removed by using the etchant comprising fluorine.

14. The method of claim 12, wherein the first wiring pattern is removed by using an etchant not comprising fluorine, and the first buffer pattern is removed by using an etching gas.

15. The method of claim 12, further comprising:
forming a second buffer pattern, the second buffer pattern being disposed between the embossed pattern and the gate pattern,
wherein forming the gate pattern comprises:
forming a second wiring layer on the embossed pattern; and
forming a second wiring pattern on the embossed pattern by patterning the second wiring layer by using the etchant comprising fluorine.

16. The method of claim 11, further comprising
forming a first buffer layer and a first wiring layer on a planar surface of the substrate before forming the gate pattern;
forming a first buffer pattern and a first wiring pattern by patterning the first buffer layer and the first wiring layer; and
removing the first wiring pattern.

17. The method of claim 16, further comprising:
forming a second buffer layer and a second wiring layer on the substrate having the first buffer pattern formed on the embossed pattern; and
forming a second wiring pattern formed on the first buffer pattern by patterning the second buffer layer and the second wiring layer by using an etchant comprising fluorine.

18. The method of claim 16, wherein forming the gate pattern comprises:
forming a second wiring layer on the substrate having the first buffer pattern formed on the embossed pattern; and
forming a second wiring pattern formed on the first buffer pattern by patterning the second wiring layer by using an etchant not comprising fluorine.

19. The method of claim 16, wherein the first buffer pattern and the first wiring pattern are formed by patterning the first buffer layer and the first wiring layer by using an etchant comprising fluorine.

20. The method of claim 16, wherein forming the first buffer pattern and the first wiring pattern comprises:
patterning the first wiring layer by using an etchant not comprising fluorine; and
patterning the first buffer layer by using an etchant comprising fluorine.
